(19) United States
(12) Patent Application Publication
(10) Pub. No.: US 2024/0333235 A1
(43) Pub. Date: Oct. 3, 2024

(54) HIGH-FREQUENCY AMPLIFIER CIRCUIT

(71) Applicant: Murata Manufacturing Co., Ltd., Kyoto (JP)

(72) Inventor: Takaaki BENI, Kyoto (JP)

(21) Appl. No.: 18/617,863

(22) Filed: Mar. 27, 2024

(30) Foreign Application Priority Data
Mar. 30, 2023 (JP) 2023-055043

(51) Int. Cl. H03F 3/21

(52) U.S. Cl. CPC H03F 3/211; H03F 2200/09; H03F 2200/451

(57) ABSTRACT

A drive stage amplifier circuit including drive stage transistors is arranged on a substrate. A balun that converts a high-frequency signal output from the drive stage amplifier circuit to a differential signal is arranged on the substrate. A power stage differential amplifier circuit that includes power stage transistors and amplifies the differential signal converted by the balun is arranged on the substrate. A drive stage power supply terminal supplies power to the drive stage transistors via the balun. When the substrate is viewed in plan view, a minimum encompassing rectangle that encompasses the power stage transistors is long in a first direction. The balun is arranged within a range of the minimum encompassing rectangle with respect to the first direction. The drive stage power supply terminal and the drive stage transistors are arranged at positions sandwiching the balun in the first direction.

### CROSS REFERENCE TO RELATED APPLICATION

This application claims priority from Japanese Patent Application No. 2023-055043 filed on Mar. 30, 2023. The content of this application is incorporated herein by reference in its entirety.

### BACKGROUND ART

The present disclosure relates to a high-frequency amplifier circuit.

A high-frequency amplifier circuit using a heterojunction bipolar transistor is known (Japanese Unexamined Patent Application Publication No. 2022-051054). The high-frequency amplifier circuit disclosed in Japanese Unexamined Patent Application Publication No. 2022-051054 has a two-stage configuration of a drive stage amplifier circuit and a power stage amplifier circuit. For example, a differential amplifier circuit is used as the power stage amplifier circuit. A single-ended signal amplified by the drive stage amplifier circuit is converted to a differential signal by a balun, and the differential signal is input to the power stage amplifier circuit.

The drive stage amplifier circuit, the balun, and the power stage amplifier circuit are arranged along a virtual straight line so that two differential transmission lines constituting the differential circuit are arranged substantially in line symmetry with respect to the virtual straight line. An input matching circuit is arranged on one side of the virtual straight line, and a bias circuit is arranged on the other side.

### BRIEF SUMMARY

It is known that, according to layout designs of a plurality of components of a high-frequency amplifier circuit conducted by the inventor of the present application, a dead space where no components are arranged is generated on the substrate, and it is difficult to reduce the dead space. The generated dead space makes it difficult to miniaturize the high-frequency amplifier circuit. When the power stage amplifier circuit is a differential amplifier circuit, it is desirable to suppress the symmetry break of the arrangement of the transmission lines for the single-ended signal and the differential signal. If the plurality of components is arranged focusing on miniaturization only, the symmetry break will increase, resulting in deteriorated characteristics.

The present disclosure provides a high-frequency amplifier circuit that can suppress degradation of characteristics while achieving miniaturization.

A high-frequency amplifier circuit according to one aspect of the present disclosure includes:
a substrate;
a drive stage amplifier circuit arranged on the substrate and including a plurality of drive stage transistors;
a balun arranged on the substrate and converting a high-frequency signal output from the drive stage amplifier circuit into a differential signal;
a power stage differential amplifier circuit arranged on the substrate and including a plurality of power stage transistors and amplifying the differential signal converted by the balun; and
a drive stage power supply terminal that supplies power to the plurality of drive stage transistors via the balun,
wherein
when the substrate is viewed in plan view, a minimum encompassing rectangle that encompasses the plurality of power stage transistors is long in a first direction,
the balun is arranged within a range of the minimum encompassing rectangle with respect to the first direction, and
the drive stage power supply terminal and the plurality of drive stage transistors are arranged at positions sandwiching the balun in the first direction.

By arranging the drive stage power supply terminal, the drive stage amplifier circuit, and the power stage differential amplifier circuit as described above, it is possible to reduce the dead space and achieve miniaturization while suppressing the degradation of the characteristics of the high-frequency amplifier circuit.

### BRIEF DESCRIPTION OF THE DRAWINGS

FIG. 1 is a block diagram of a high-frequency amplifier circuit according to an embodiment;

FIG. 2 is an equivalent circuit diagram of a plurality of components from a signal input terminal to a balun;

FIG. 3 is an equivalent circuit diagram of a plurality of components from the balun to a non-inverted signal output terminal and an inverted signal output terminal;

FIG. 4 is an equivalent circuit diagram of a drive stage bias circuit and a power stage bias circuit;

FIG. 5A is a schematic plan view of one power stage transistor, and FIG. 5B is a cross-sectional view taken along the dot-and-dash line 5B-5B in FIG. 5A;

FIG. 6 is a view showing the positional relationship of a plurality of components of a power stage differential amplifier circuit in plan view;

FIG. 7 is a view showing the positional relationship of a plurality of components of a drive stage amplifier circuit and the balun in plan view;

FIG. 8 is a view showing the arrangement of a plurality of components of the high-frequency amplifier circuit in plan view;

FIG. 9 is a view showing the arrangement of a plurality of components of a high-frequency amplifier circuit according to a comparative example in plan view;

FIG. 10 is a graph showing simulation results of the AMAM characteristics of the high-frequency amplifier circuit according to the embodiment shown in FIG. 8 and the high-frequency amplifier circuit according to the comparative example shown in FIG. 9;

FIG. 11 is a view showing, in plan view, the positional relationship between a drive stage amplifier circuit, a balun, and a drive stage power supply terminals of a high-frequency amplifier circuit according to another comparative example; and

FIG. 12 is a graph showing simulation results of the AMAM characteristics of the high-frequency amplifier circuit according to the embodiment shown in FIG. 8 and the high-frequency amplifier circuit according to the comparative example shown in FIG. 11.

### DETAILED DESCRIPTION

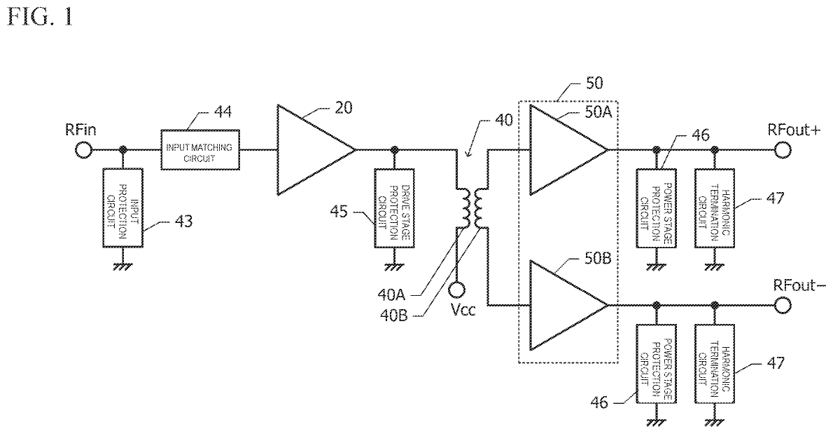

A high-frequency amplifier circuit according to an embodiment will be described below with reference to FIG. 1 to FIG. 12.

FIG. 1 is a block diagram of the high-frequency amplifier circuit according to the embodiment. A plurality of components of the high-frequency amplifier circuit according to the embodiment are formed on a single common substrate. A high-frequency signal, which is a single-ended signal, is input to the high-frequency amplifier circuit from a signal input terminal RFin. The high-frequency signal input from the signal input terminal RFin is input to a drive stage amplifier circuit 20 via an input matching circuit 44.

The high-frequency signal amplified by the drive stage amplifier circuit 20 is converted to a differential signal by a balun 40, and the differential signal is input to a power stage differential amplifier circuit 50. Specifically, the output node of the drive stage amplifier circuit 20 is connected to one end portion of a primary coil 40A of the balun 40, and the other end portion of the primary coil 40A of the balun 40 is connected to a drive stage power supply terminal Vcc. Two end portions of a secondary coil 40B of the balun 40 are connected to the respective input nodes of a non-inverted signal amplifier circuit 50A and an inverted signal amplifier circuit 50B of the power stage differential amplifier circuit 50. The power is supplied from the drive stage power supply terminal Vcc to the drive stage amplifier circuit 20 via the primary coil 40A of the balun 40. A middle tap of the secondary coil 40B of the balun 40 may be grounded. In such a case, the symmetry of the balun 40 can be improved.

The power stage differential amplifier circuit 50 amplifies the input differential signal. The output node of the non-inverted signal amplifier circuit 50A is connected to a non-inverted signal output terminal RFout+, and the output node of the inverted signal amplifier circuit 50B is connected to an inverted signal output terminal RFout−.

An input protection circuit 43 is connected between the signal input terminal RFin and the ground. A drive stage protection circuit 45 is connected between the output node of the drive stage amplifier circuit 20 and the ground. A power stage protection circuit 46 is connected between the output node of the non-inverted signal amplifier circuit 50A and the ground, and between the output node of the inverted signal amplifier circuit 50B and the ground, respectively. Furthermore, a harmonic termination circuit 47 is connected between the output node of the non-inverted signal amplifier circuit 50A and the ground, and between the output node of the inverted signal amplifier circuit 50B and the ground, respectively.

The input protection circuit 43, the drive stage protection circuit 45, and the power stage protection circuit 46 protect elements from surge voltage and/or excessive high-frequency signal. The harmonic termination circuit 47 terminates harmonic waves output from the power stage differential amplifier circuit 50.

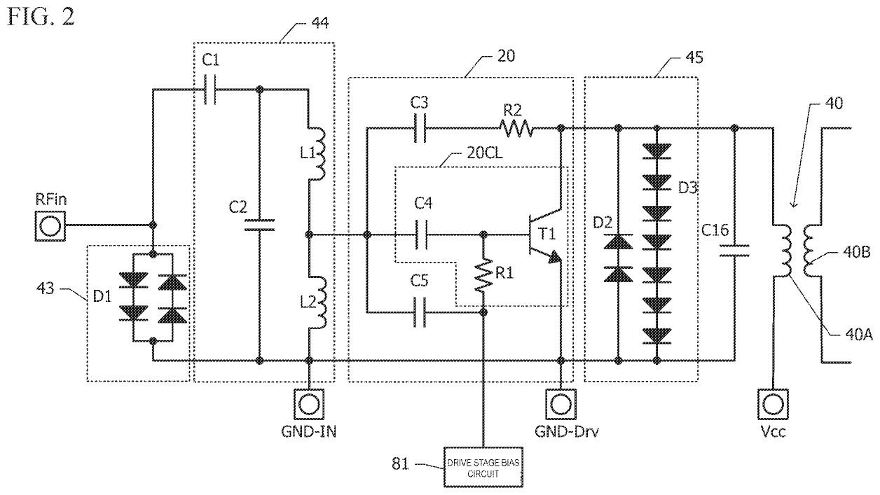

FIG. 2 is an equivalent circuit diagram of a plurality of components from the signal input terminal RFin to the balun 40. A ground potential is supplied to the ground conductor from an input side ground terminal GND-IN and a drive stage ground terminal GND-Drv.

The input protection circuit 43 connected between the signal input terminal RFin and the ground includes two clamp circuits each with two stages of diodes D1 connected. The two clamp circuits are connected in parallel in a mutually opposite polarity orientation. The input matching circuit 44 includes capacitors C1 and C2 and inductors L1 and L2.

Next, the configuration of the drive stage amplifier circuit 20 is described.

The drive stage amplifier circuit 20 includes a plurality of cells 20CL connected in parallel with each other. In FIG. 2, one cell 20CL is shown as representative. Each of the cells 20CL includes a drive stage transistor T1, an input capacitor C4, and a ballast resistive element R1. The high-frequency signal passed through the input matching circuit 44 is input to the base of the drive stage transistor T1 via the input capacitor C4. A bias is supplied to the base of the drive stage transistor T1 from a drive stage bias circuit 81 via the ballast resistive element R1.

A series circuit of a capacitor C3 and a resistive element R2 is connected between the input node and the output node of the drive stage amplifier circuit 20. A capacitor C5 is connected between the input node of the drive stage amplifier circuit 20 and an end portion of the ballast resistive element R1 on the side of the drive stage bias circuit 81.

The power is supplied from the drive stage power supply terminal Vcc to the collector of the drive stage transistor T1 via the primary coil 40A of the balun 40.

Next, the configuration of the drive stage protection circuit 45 is described.

The drive stage protection circuit 45 includes a clamp circuit with two stages of diodes D2 connected and a clamp circuit with multiple stages of diodes D3 connected. The clamp circuit including the diodes D2 is connected in a direction such that a reverse bias is formed from the output node of the drive stage amplifier circuit 20 toward the ground. The clamp circuit including the diodes D3 is connected in a direction such that a forward bias is formed from the output node of the drive stage amplifier circuit 20 toward the ground. A capacitor C16 is connected between the output node of the drive stage amplifier circuit 20 and the ground.

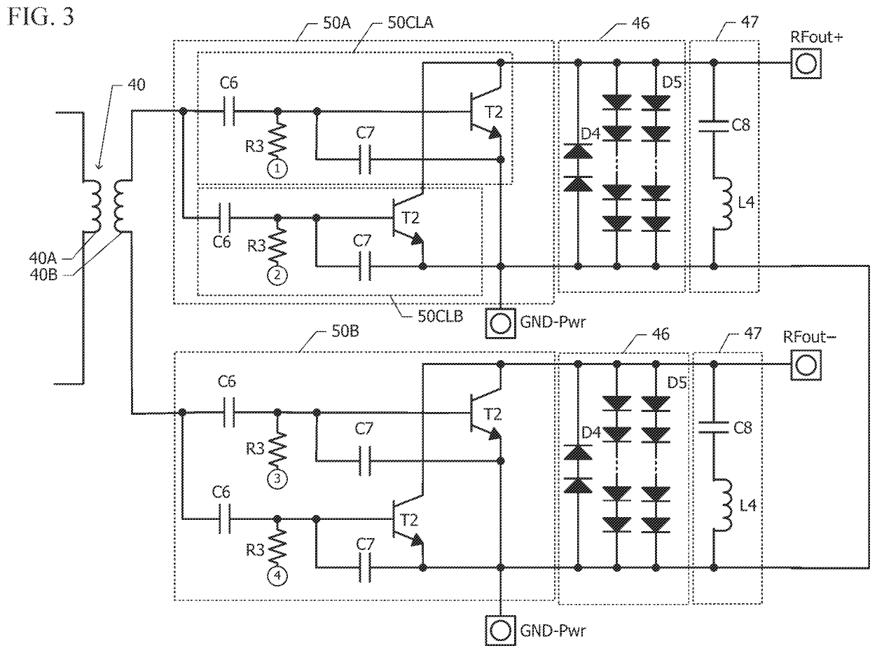

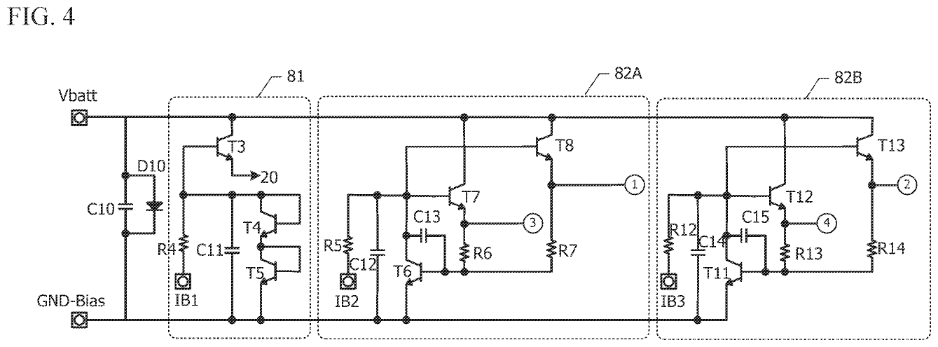

FIG. 3 is an equivalent circuit diagram of a plurality of components from the balun 40 to the non-inverted signal output terminal RFout+ and the inverted signal output terminal RFout−. The coupler marked with a circled number in FIG. 3 means that the coupler is to be connected to a coupler marked with the corresponding number shown in FIG. 4 to be described later. A ground potential is supplied to the ground conductor from two power stage ground terminals GND-Pwr.

One end portion of the secondary coil 40B of the balun 40 is connected to the input node of the non-inverted signal amplifier circuit 50A, and the other end portion is connected to the input node of the inverted signal amplifier circuit 50B. Since the configuration of the non-inverted signal amplifier circuit 50A is identical to the configuration of the inverted signal amplifier circuit 50B, the configuration of the non-inverted signal amplifier circuit 50A is described below.

The non-inverted signal amplifier circuit 50A includes a plurality of cells 50CLA and a plurality of cells 50CLB connected in parallel with each other. Each of the cells 50CLA and 50CLB includes a power stage transistor T2, an input capacitor C6, a ballast resistive element R3, and a capacitor C7 connected between the base and the emitter of the power stage transistor T2. The plurality of cells 50CLA and cells 50CLB can be biased independently of each other. One cell 50CLA and one cell 50CLB are shown in FIG. 3.

The non-inverted signal input to the input node of the non-inverted signal amplifier circuit 50A is input to the base of the power stage transistor T2 via the input capacitor C6. As indicated by a coupler 1, a bias is supplied from a power stage bias circuit 82A (FIG. 4) to the base of the power stage transistor T2 via the ballast resistive element R3 of the cell 50CLA. As indicated by a coupler 2, a bias is supplied from another power stage bias circuit 82B (FIG. 4) to the base of the power stage transistor T2 via the ballast resistive element R3 of the cell 50CLB.

In the inverted signal amplifier circuit 50B, as in the non-inverted signal amplifier circuit 50A, the ballast resistive element R3 of the cell 50CLA is connected to the power stage bias circuit 82A (FIG. 4) as indicated by a coupler 3, and the ballast resistive element R3 of the cell 50CLB is connected to the power stage bias circuit 82B (FIG. 4) as indicated by a coupler 4.

Next, the configuration of the power stage protection circuit 46 is described.

The power stage protection circuit 46 includes a clamp circuit with two stages of diodes D4 connected and two clamp circuits each with multiple stages of diodes D5 connected. The clamp circuit including the diodes D4 is connected in a direction such that a reverse bias is formed from the respective output nodes of the non-inverted signal amplifier circuit 50A and the inverted signal amplifier circuit 50B toward the ground. The two clamp circuits including the diodes D5 are connected in parallel in a direction such that a forward bias is formed from the respective output nodes of the non-inverted signal amplifier circuit 50A and the inverted signal amplifier circuit 50B toward the ground.

Next, the configuration of the harmonic termination circuit 47 is described. The harmonic termination circuit 47 includes a capacitor C8 and an inductor L4 connected in series with each other. A series-connected circuit of the capacitor C8 and the inductor L4 is connected between the respective output nodes of the non-inverted signal amplifier circuit 50A and the inverted signal amplifier circuit 50B and the ground.

The power is supplied from the non-inverted signal output terminal RFout+ to the collector of the power stage transistor T2 of the non-inverted signal amplifier circuit 50A. The power is supplied from the inverted signal output terminal RFout− to the collector of the power stage transistor T2 of the inverted signal amplifier circuit 50B.

FIG. 4 is an equivalent circuit diagram of the drive stage bias circuit 81 and the power stage bias circuits 82A and 82B. The power for bias is supplied from a bias power supply terminal Vbatt to the drive stage bias circuit 81 and the power stage bias circuits 82A and 82B. A ground potential is supplied from a bias ground terminal GND-Bias to the ground conductor of the drive stage bias circuit 81 and the power stage bias circuits 82A and 82B.

A capacitor C10 is connected between the bias power supply terminal Vbatt and the ground. Furthermore, a diode D10 is connected in a direction such that a forward bias is formed from the bias power supply terminal Vbatt toward the ground.

The drive stage bias circuit 81 includes transistors T3, T4 and T5, a capacitor C11, and a resistive element R4. The emitter of the transistor T3 is connected to the base of the drive stage transistor T1 (FIG. 2) via the ballast resistive element R1 (FIG. 2). The drive stage bias circuit 81 supplies a bias to the drive stage amplifier circuit 20 based on a control signal input from a drive stage bias control terminal IB1.

The power stage bias circuit 82A includes transistors T6, T7, T8, T9 and T10, capacitors C12 and C13, and resistive elements R5, R6, R7, R8, R9, R10 and R11. As indicated by the coupler 1, the emitters of the transistors T8 and T10 are connected to the base of the power stage transistor T2 via the ballast resistive element R3 (FIG. 3) of the cell 50CLA of the non-inverted signal amplifier circuit 50A. As indicated by the coupler 3, the emitters of the transistors T7 and T9 are connected to the base of the power stage transistor T2 via the ballast resistive element R3 (FIG. 3) of the cell 50CLA of the inverted signal amplifier circuit 50B.

The power stage bias circuit 82A supplies a bias to the cell 50CLA of the power stage differential amplifier circuit 50 based on a control signal input from a power stage bias control terminal IB2.

The power stage bias circuit 82B includes transistors T11, T12 and T13, capacitors C14 and C15, and resistive elements R12, R13 and R14. As indicated by the coupler 2, the emitter of the transistor T13 is connected to the base of the power stage transistor T2 via the ballast resistive element R3 (FIG. 3) of the cell 50CLB of the non-inverted signal amplifier circuit 50A. As indicated by the coupler 4, the emitter of the transistor T12 is connected to the base of the power stage transistor T2 via the ballast resistive element R3 (FIG. 3) of the cell 50CLB of the inverted signal amplifier circuit 50B.

The power stage bias circuit 82B supplies a bias to the cell 50CLB of the power stage differential amplifier circuit 50 based on a control signal input from a power stage bias control terminal IB3.

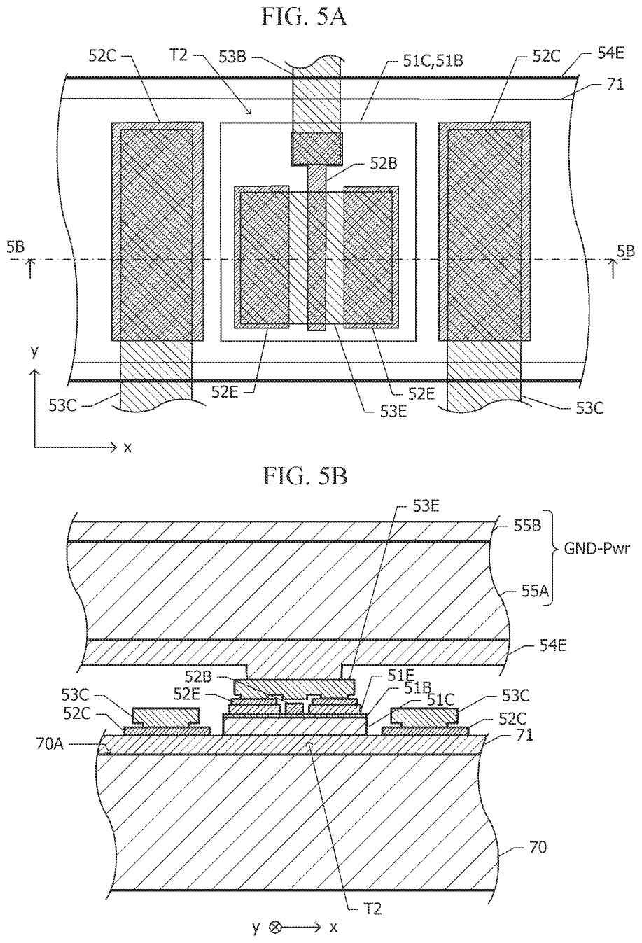

FIG. 5A is a schematic plan view of one power stage transistor T2, and FIG. 5B is a cross-sectional view taken along the dot-and-dash line 5B-5B in FIG. 5A. In FIG. 5A, electrodes in direct contact with a semiconductor layer are shown by a right-up relative dark hatching, and wirings in the first wiring layer are shown by a right-down relative light hatching. In FIG. 5B, the interlayer insulation film is omitted. The basic configuration of the drive stage transistor T1 is identical to the basic configuration of the power stage transistor T2.

As shown in FIG. 5B, a sub-collector layer 71 is arranged on a first surface 70A, which is one surface of a substrate 70. Hereinafter, the surface of each component of the high-frequency amplifier circuit that faces in the same direction as the first surface 70A is referred to as an upper surface. The substrate 70 is a substrate made of semi-insulating compound semiconductor, and the sub-collector layer 71 is formed by epitaxially growing a layer made of the same compound semiconductor as the substrate 70, for example, on the first surface 70A of the substrate 70. The sub-collector layer 71 is imparted with n-type conductivity. As an example, the substrate 70 is a GaAs substrate and the sub-collector layer 71 is formed of n-type GaAs.

An xy Cartesian coordinate system is defined with a plane parallel to the first surface 70A of the substrate 70 as the xy plane. A plurality of power stage transistors T2 are arranged side by side in the x direction on the upper surface of the sub-collector layer 71. The power stage transistor T2 includes a collector layer 51C, a base layer 51B, and an emitter layer 51E stacked in this order from the sub-collector layer 71 side. A heterojunction bipolar transistor is used as the power stage transistor T2. For example, the collector layer 51C is formed of n-type GaAs, the base layer 51B is formed of p-type GaAs, and the emitter layer 51E is formed of n-type InGaP.

Two emitter layers 51E are arranged on the upper surface of the base layer 51B, spaced apart in the x direction. In this specification, a mesa structure consisting of the collector layer 51C and the base layer 51B is referred to as a collector mesa.

Two emitter electrodes 52E are arranged on the two respective emitter layers 51E. A base electrode 52B is arranged in an area between the two emitter layers 51E on the upper surface of the base layer 51B. Two collector electrodes 52C are arranged sandwiching the collector mesa in the x direction on the upper surfaces of the sub-collector layer 71. The collector electrode 52C is electrically connected to the collector layer 51C via the sub-collector layer 71. The collector electrode 52C is located between two power stage transistors T2 arranged in the x direction and is shared by the two power stage transistors T2.

A first layer emitter wiring 53E is arranged on the two emitter electrodes 52E. The emitter wiring 53E passes above the base electrode 52B and electrically connects the two emitter electrodes 52E to each other. A first layer collector wiring 53C is arranged on the collector electrode 52C.

A second layer emitter wiring 54E is electrically connected to the first layer emitter wiring 53E. The power stage ground terminal GND-Pwr is arranged on the second layer emitter wiring 54E. The power stage ground terminal GND-Pwr includes a pillar portion 55a and a solder layer 55b arranged on the upper surface of the pillar portion 55a. An under bump metal layer may be arranged between the pillar portion 55a and the second layer emitter wiring 54E according to necessity.

As shown in FIG. 5A, a collector mesa consisting of the collector layer 51C and the base layer 51B is arranged within the sub-collector layer 71 in plan view. Two collector electrodes 52C are arranged sandwiching the collector mesa in the x direction. Two first layer collector wirings 53C overlap the two respective collector electrodes 52C. The first layer collector wiring 53C extends to the outer side portion of the sub-collector layer 71 in the negative direction of the y-axis.

The two emitter electrodes 52E long in the y direction are arranged inside the collector mesa so as to be spaced apart in the x direction, and the base electrode 52B long in the y direction is arranged between the two emitter electrodes 52E. One first layer emitter wiring 53E is arranged to overlap the two emitter electrodes 52E. The first layer emitter wiring 53E reaches from one emitter electrode 52E to the other emitter electrode 52E, crossing the base electrode 52B. A first layer base wiring 53B is arranged so as to overlap the end portion of the base electrode 52B. The first layer base wiring 53B extends to the outer side portion of the sub-collector layer 71 in the positive direction of the y-axis.

The second layer emitter wiring 54E is arranged to overlap the first layer emitter wiring 53E. The second layer emitter wiring 54E extends in the x direction and connects the first layer emitter wiring 53E provided to each power stage transistor T2 with each other.

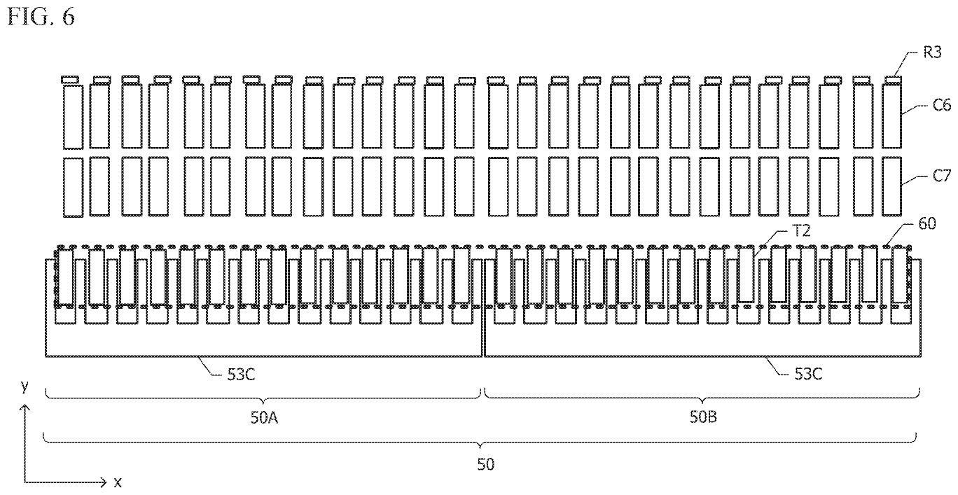

FIG. 6 is a view showing the positional relationship of a plurality of components of the power stage differential amplifier circuit 50 in plan view. The plurality of power stage transistors T2 are arranged side by side in the x direction. Each of the plurality of power stage transistors T2 shown in FIG. 6 represents the position and shape in plan view of the collector mesa consisting of the collector layer 51C and the base layer 51B (FIGS. 5A and 5B). When the center of the transistor row consisting of the plurality of power stage transistors T2 aligned in the x direction is regarded as a boundary, a plurality of power stage transistors T2 arranged on one side of the boundary constitute the non-inverted signal amplifier circuit 50A (FIG. 3), and a plurality of power stage transistors T2 arranged on the other side of the boundary constitute the inverted signal amplifier circuit 50B (FIG. 3).

Each of the plurality of power stage transistors T2 is provided with one capacitor C7, one input capacitor C6, and one ballast resistive element R3. The capacitor C7, the input capacitor C6, and the ballast resistive element R3 are arranged in this order along a straight line extending from the corresponding power stage transistor T2 to the positive direction of the y-axis.

A comb-shaped collector wiring 53C is connected to each of the non-inverted signal amplifier circuit 50A and the inverted signal amplifier circuit 50B. The power stage transistor T2 is arranged between the comb-tooth portions of the collector wiring 53C.

A minimum encompassing rectangle 60 that encompasses the plurality of power stage transistors T2 is defined in plan view. The minimum encompassing rectangle 60 is a convex closure that encompasses the collector mesas of the plurality of power stage transistors T2. The long side of the minimum encompassing rectangle 60 is parallel to the x-axis and the short side is parallel to the y-axis.

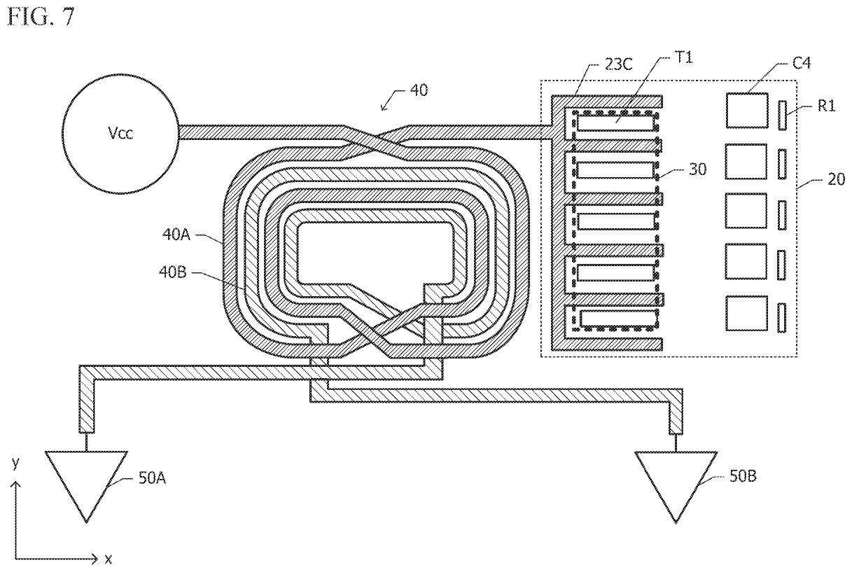

FIG. 7 is a view showing the positional relationship of a plurality of components of the drive stage amplifier circuit 20 and the balun 40 in plan view. A plurality of drive stage transistors T1 are arranged side by side in the y direction. In other words, the arrangement direction of the power stage transistor T2 and the arrangement direction of the drive stage transistor T1 are orthogonal to each other. In FIG. 7, each of the plurality of drive stage transistors T1 represents the position and shape in plan view of the collector mesa consisting of the collector layer and the base layer of the drive stage transistor T1.

A minimum encompassing rectangle 30 that encompasses the plurality of drive stage transistors T1 is defined in plan view. The minimum encompassing rectangle 30 is a convex closure that encompasses the collector mesas of the plurality of drive stage transistors T1. The long side of the minimum encompassing rectangle 30 is parallel to the y-axis and the short side is parallel to the x-axis.

Each of the plurality of drive stage transistors T1 is provided with one input capacitor C4 and one ballast resistive element R1. The input capacitor C4 and the ballast resistive element R1 are arranged in this order along a straight line extending from the corresponding drive stage transistor T1 to the positive direction of the x-axis. The plurality of respective drive stage transistors T1 are arranged between a plurality of comb-tooth portions of a comb-shaped collector wiring 23C.

The balun 40 consists of the primary coil 40A and the secondary coil 40B arranged in a plurality of wiring layers. In FIG. 7, the primary coil 40A and the collector wiring 53C are shown by a right-up relative dark hatching, and the secondary coil 40B is shown by a right-down relative light hatching. The number of turns of each of the primary coil 40A and the secondary coil 40B is approximately 2. The insulation between the wires is ensured at the intersections between the wires of the primary coil 40A, at the intersections between the wires of the secondary coil 40B, and at the intersections between the primary coil 40A and the secondary coil 40B.

The collector wiring 23C is connected to one end portion of the primary coil 40A, and the drive stage power supply terminal Vcc is connected to the other end portion. The input node of the non-inverted signal amplifier circuit 50A is connected to one end portion of the secondary coil 40B, and the input node of the inverted signal amplifier circuit 50B is connected to the other end portion.

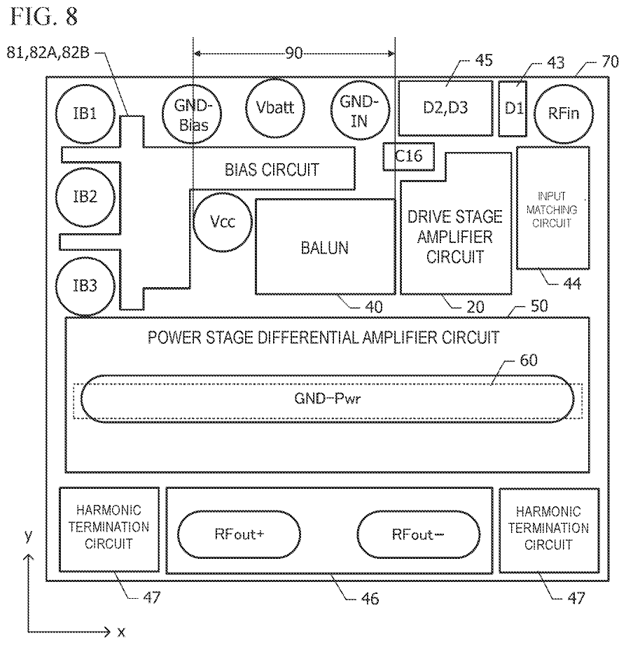

FIG. 8 is a view showing the arrangement of a plurality of components of the high-frequency amplifier circuit according to the present embodiment in plan view. The substrate 70 is square or rectangular in plan view. An xy Cartesian coordinate system is defined with a direction parallel to one side of the substrate 70 as the x direction. The power stage differential amplifier circuit 50 is disposed substantially over the entire area of the substrate 70 in the x direction. In plan view, the minimum encompassing rectangle 60 that encompasses the plurality of power stage transistors T2 is defined within the area where the power stage differential amplifier circuit 50 is arranged. The power stage ground terminal GND-Pwr is arranged so that it overlaps the minimum encompassing rectangle 60.

The following components are arranged on the positive side of the y-axis relative to the area where the power stage differential amplifier circuit 50 is located: the drive stage amplifier circuit 20, the balun 40, the drive stage bias circuit 81, the power stage bias circuits 82A and 82B, the input protection circuit 43, the input matching circuit 44, the drive stage protection circuit 45, the signal input terminal RFin, the drive stage power supply terminal Vcc, the input side ground terminal GND-IN, the bias ground terminal GND-Bias, the bias power supply terminal Vbatt, the drive stage bias control terminal IB1, the power stage bias control terminals IB2 and IB3, and the capacitor C16 (FIG. 2). The power stage protection circuit 46 and the harmonic termination circuit 47 are arranged on the negative side of the y-axis relative to the area where the power stage differential amplifier circuit 50 is located. The non-inverted signal output terminal RFout+ and the inverted signal output terminal RFout− are arranged within the area where the power stage protection circuit 46 is located.

The balun 40 is arranged within the range of the minimum encompassing rectangle 60 of the plurality of power stage transistors T2 with respect to the x direction. More specifically, the balun 40 is arranged on a virtual straight line extending in the y direction from the center position of the minimum encompassing rectangle 60. In other words, the boundary between the area where the power stage transistor T2 of the non-inverted signal amplifier circuit 50A (FIG. 6) are distributed and the area where the power stage transistor T2 of the inverted signal amplifier circuit 50B (FIG. 6) are distributed is located within the range of the balun 40 in the x direction.

The drive stage power supply terminal Vcc and the plurality of drive stage transistors T1 (i.e., the minimum encompassing rectangle 30 (FIG. 7)) are arranged at positions sandwiching the balun 40 in the x direction. In other words, the balun 40 is arranged on the positive side of the x-axis from the drive stage power supply terminal Vcc, and the drive stage amplifier circuit 20 is arranged on the positive side of the x-axis from the balun 40. With respect to the y direction, the range of the drive stage power supply terminal Vcc, the range of the minimum encompassing rectangle 30, and the range of the balun 40 in the y direction partially overlap each other.

When viewed from the balun 40, the input matching circuit 44 is arranged at a position farther than the drive stage amplifier circuit 20 in the x direction. In other words, the input matching circuit 44 is arranged on the positive side of the x-axis from the drive stage amplifier circuit 20. When viewed from the power stage differential amplifier circuit 50, the signal input terminal RFin is arranged at a position farther than the input matching circuit 44 in the y direction. In other words, the signal input terminal RFin is arranged on the positive side of the y-axis from the input matching circuit 44. When viewed from the balun 40, the signal input terminal RFin is arranged at a position farther than the drive stage amplifier circuit 20 in the x direction.

The bias power supply terminal Vbatt is arranged within a range 90 in which the drive stage power supply terminal Vcc and the balun 40 are distributed with respect to the x direction. The input side ground terminal GND-IN is arranged between the bias power supply terminal Vbatt and the signal input terminal RFin with respect to the x direction.

The range in which the drive stage bias circuit 81 and the power stage bias circuits 82A and 82B are arranged and the range in which the balun 40 is arranged partially overlap each other with respect to the y direction.

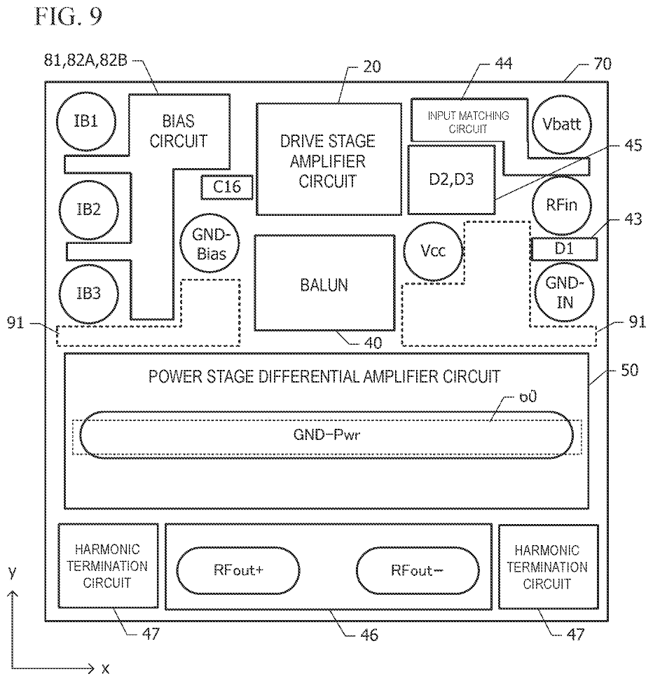

Next, the excellent effects of the present embodiment are explained by comparison with a comparative example shown in FIG. 9.

FIG. 9 is a view showing the arrangement of a plurality of components of a high-frequency amplifier circuit according to the comparative example in plan view. In the embodiment shown in FIG. 8, the drive stage amplifier circuit 20, the balun 40, and the drive stage power supply terminal Vcc are arranged side by side in the x direction and are located on the positive side of the y-axis relative to the power stage differential amplifier circuit 50.

In contrast, in the comparative example shown in FIG. 9, a drive stage amplifier circuit 20, a balun 40, and a power stage differential amplifier circuit 50 are arranged side by side in the y direction, taking into account the symmetry of the differential circuit. In particular, the drive stage amplifier circuit 20, the balun 40, and the power stage differential amplifier circuit 50 are arranged so that they are substantially in line symmetry with respect to a virtual straight line parallel to the y-axis. The high-frequency signal is transmitted in the y direction from the drive stage amplifier circuit 20 to the power stage differential amplifier circuit 50 via the balun 40.

Since the drive stage amplifier circuit 20, the balun 40, and the power stage differential amplifier circuit 50, which occupy relatively large areas within the surface of the substrate 70, are arranged side by side in the y direction, it is difficult to reduce the dimension of the substrate 70 in the y direction. For example, as shown in FIG. 9, there is a dead space 91 where no elements are arranged.

In the embodiment shown in FIG. 8, the drive stage amplifier circuit 20 and the balun 40 are arranged side by side in the x direction, therefore it is possible to reduce the dead space and reduce the dimension of the substrate 70 in the y direction. In the layout design by the inventor of the present application, it has been confirmed that the dimension of the chip of the high-frequency amplifier circuit according to the embodiment shown in FIG. 8 in the y direction can be reduced to about 95% of the dimension of the chip of the high-frequency amplifier circuit according to the comparative example shown in FIG. 9 in the y direction. Since the dimension of the substrate 70 in the x direction is determined by the dimension of the power stage differential amplifier circuit 50 in the x direction, there is no difference in the dimension of the substrate 70 in the x direction between the embodiment shown in FIG. 8 and the comparative example shown in FIG. 9.

In the present embodiment (FIG. 7), the drive stage power supply terminal Vcc for supplying power to the drive stage amplifier circuit 20 via the balun 40 is arranged on the opposite side of the drive stage amplifier circuit 20 when viewed from the balun 40. The single-ended signal output from the drive stage amplifier circuit 20 is input to the primary coil 40A of the balun 40 from the positive side of the x-axis and output to the negative side of the x-axis via the primary coil 40A. The non-inverted signal and the inverted signal that constitute the differential signal are output from the secondary coil 40B of the balun 40 to the negative side of the y-axis. Thus, the symmetry break of the differential circuit with respect to the virtual straight line parallel to the y-axis is suppressed.

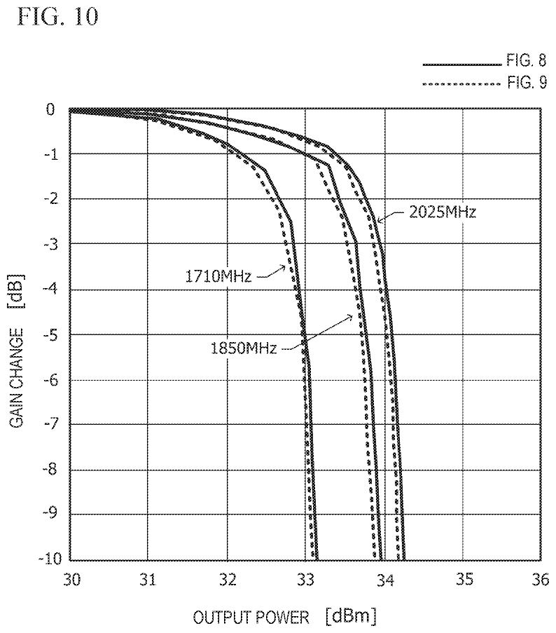

Simulation results of the AMAM characteristics of the high-frequency amplifier circuit according to the embodiment shown in FIG. 8 and the high-frequency amplifier circuit according to the comparative example shown in FIG. 9 will be described below with reference to FIG. 10. FIG. 10 is a graph showing the simulation results of the AMAM characteristics. The horizontal axis represents the output power in unit [dBm], and the vertical axis represents the gain change in unit [dB] with the gain when the output power is 30 dBm as a reference. The solid line and the dashed line in the graph shown in FIG. 10 indicate the AMAM characteristics of the high-frequency amplifier circuit according to the embodiment shown in FIG. 8 and the AMAM characteristics of the high-frequency amplifier circuit according to the comparative example shown in FIG. 9, respectively. The simulations were performed at three frequencies: 1710 MHz, 1850 MHZ, and 2025 MHz.

It is known that the AMAM characteristics of the high-frequency amplifier circuit according to the embodiment shown in FIG. 8 are not inferior to the AMAM characteristics of the high-frequency amplifier circuit according to the comparative example shown in FIG. 9. Furthermore, in the embodiment shown in FIG. 8, saturation output is improved compared to the comparative example shown in FIG. 9.

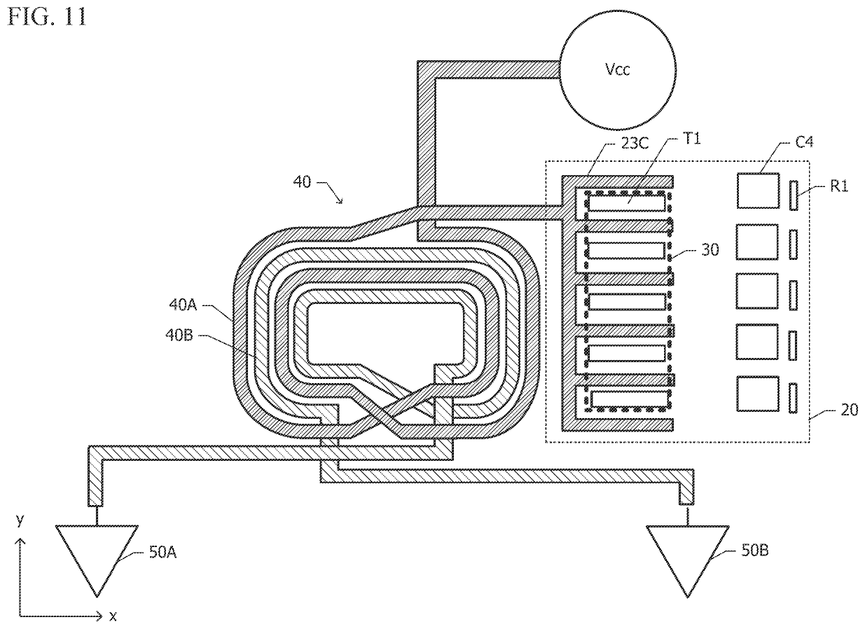

Next, the excellent effects of the present embodiment are explained by comparison with another comparative example shown in FIG. 11. FIG. 11 is a view showing, in plan view, the positional relationship between a drive stage amplifier circuit 20, a balun 40, and a drive stage power supply terminal Vcc of a high-frequency amplifier circuit according to the comparative example.

In the embodiment shown in FIG. 7, the drive stage amplifier circuit 20 and the drive stage power supply terminal Vcc are arranged on opposite sides from each other with respect to the x direction with reference to the balun 40. In contrast, in the comparative example shown in FIG. 11, the drive stage amplifier circuit 20 and the drive stage power supply terminal Vcc are both arranged on the same side with respect to the x direction with reference to the balun 40, and are both arranged side by side in the y direction. Specifically, when viewed from the balun 40, the drive stage amplifier circuit 20 and the drive stage power supply terminal Vcc are both arranged on the positive side of the x-axis. Therefore, the single-ended signal output from the drive stage amplifier circuit 20 is input to the primary coil 40A of the balun 40 from the positive side of the x-axis and output to the positive side of the x-axis via the primary coil 40A. Therefore, the symmetry break of the differential circuit with respect to the virtual straight line parallel to the y-axis increases.

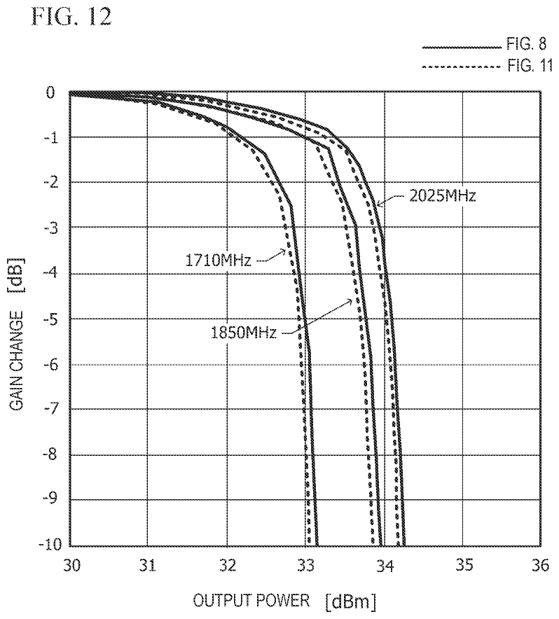

FIG. 12 is a graph showing simulation results of the AMAM characteristics of the high-frequency amplifier circuit according to the embodiment shown in FIG. 8 and the high-frequency amplifier circuit according to the comparative example shown in FIG. 11. The horizontal axis represents the output power in unit [dBm], and the vertical axis represents the gain change in unit [dB] with the gain when the output power is 30 dBm as a reference. The solid line and the dashed line in the graph shown in FIG. 12 indicate the AMAM characteristics of the high-frequency amplifier circuit according to the embodiment shown in FIG. 8 and the AMAM characteristics of the high-frequency amplifier circuit according to the comparative example shown in FIG. 11, respectively. The simulations were performed at three frequencies: 1710 MHz, 1850 MHZ, and 2025 MHz.

It is known that, in the comparative example shown in FIG. 11, the reduction in gain is large and the saturation output is low compared with the embodiment shown in FIG. 8. The simulations, the results of which are shown in FIG. 12, confirm the excellent effect of reducing the symmetry break by arranging the drive stage amplifier circuit 20 and the drive stage power supply terminal Vcc to sandwich the balun 40 in the x direction, as in the embodiment shown in FIG. 8.

In the configuration of the above embodiment (FIG. 7), the distance from the drive stage power supply terminal Vcc to the drive stage amplifier circuit 20 is longer than the configuration of the comparative example (FIG. 11). Therefore, the parasitic capacitance between the drive stage power supply terminal Vcc and the drive stage amplifier circuit 20 is reduced. Thus, the degradation of characteristics caused by the parasitic capacitance is suppressed. In addition, disposing the drive stage power supply terminal Vcc and the drive stage amplifier circuit 20 side by side in the y direction, as in the comparative example (FIG. 11), is also not necessarily suitable in terms of reducing the dimension of the chip in the y direction.

Next, other excellent effects of the above embodiment will be described. In the above embodiment (FIG. 8), the bias power supply terminal Vbatt is arranged within the range 90 in which the drive stage power supply terminal Vcc and the balun 40 are distributed with respect to the x direction. Furthermore, the signal input terminal RFin is arranged side by side with respect to the input matching circuit 44 in the y direction. In other words, the drive stage amplifier circuit 20 is arranged between the position where the signal input terminal RFin is arranged and the position where the bias power supply terminal Vbatt is arranged with respect to the x direction. Therefore, the distance from the signal input terminal RFin to the bias power supply terminal Vbatt is longer than the dimension of the drive stage amplifier circuit 20 in the x direction.

Furthermore, the balun 40 and the drive stage amplifier circuit 20 are arranged between the position where the signal input terminal RFin is arranged and the position where the drive stage power supply terminal Vcc is arranged with respect to the x direction. Therefore, the distance from the signal input terminal RFin to the drive stage power supply terminal Vcc is longer than the total dimension of the balun 40 and the drive stage amplifier circuit 20 in the x direction.

Thus, in the above embodiment, the signal input terminal RFin is located away from the power supply terminal. Thus, oscillation due to sneak signal can be suppressed.

The above embodiments are illustrative and the present disclosure is not limited to the above embodiments. It should be obvious to those skilled in the art that various modifications, improvements, combinations, and the like can be made.

Based on the above embodiments described in this description, the following disclosure is disclosed.

<1>

A high-frequency amplifier circuit comprising:
a substrate;
a drive stage amplifier circuit arranged on the substrate and including a plurality of drive stage transistors;
a balun arranged on the substrate and converting a high-frequency signal output from the drive stage amplifier circuit into a differential signal;
a power stage differential amplifier circuit arranged on the substrate and including a plurality of power stage transistors and amplifying the differential signal converted by the balun; and
a drive stage power supply terminal that supplies power to the plurality of drive stage transistors via the balun,
wherein
when the substrate is viewed in plan view, a minimum encompassing rectangle that encompasses the plurality of power stage transistors is long in a first direction,
the balun is arranged within the range of the minimum encompassing rectangle with respect to the first direction, and
the drive stage power supply terminal and the plurality of drive stage transistors are arranged at positions sandwiching the balun in the first direction.
   <2>

The high-frequency amplifier circuit according to <1>, wherein the plurality of power stage transistors are arranged side by side in the first direction.

<3>

The high-frequency amplifier circuit according to <1> or <2>, wherein the plurality of drive stage transistors are arranged side by side in a direction orthogonal to the first direction on the surface of the substrate.

<4>

The high-frequency amplifier circuit according to <1> or <2>, further comprising:
a signal input terminal to which a signal is input to the drive stage amplifier circuit;
a drive stage bias circuit that supplies a bias to the plurality of drive stage transistors;
a power stage bias circuit that supplies a bias to the plurality of power stage transistors; and
a bias power supply terminal that supplies power to the drive stage bias circuit and the power stage bias circuit,
wherein
when viewed from the balun, the signal input terminal is arranged at a position farther than the drive stage amplifier circuit in the first direction, and
the bias power supply terminal is arranged within a range where the drive stage power supply terminal and the balun are distributed with respect to the first direction.

What is claimed is:

1. A high-frequency amplifier circuit comprising:
a substrate;
a drive stage amplifier circuit on the substrate and comprising a plurality of drive stage transistors;
a balun on the substrate and configured to convert a high-frequency signal output from the drive stage amplifier circuit into a differential signal;
a power stage differential amplifier circuit on the substrate, comprising a plurality of power stage transistors, and configured to amplify the differential signal converted by the balun; and
a drive stage power supply terminal configured to supply power to the plurality of drive stage transistors via the balun,
wherein when the substrate is viewed in plan view, long sides of a minimally-sized rectangle that encompasses the plurality of power stage transistors extend along a first direction and short sides of the minimally-sized rectangle extend along a second direction,
wherein the balun is outside of the minimally-sized with respect to the second direction, and between the short sides of the minimally-sized rectangle with respect to the first direction, and
wherein the drive stage power supply terminal is on the substrate at an opposite of the balun than the plurality of drive stage transistors in the second direction.

2. The high-frequency amplifier circuit according to claim 1, wherein the plurality of power stage transistors are side by side on the substrate in the first direction.

3. The high-frequency amplifier circuit according to claim 1, wherein the plurality of drive stage transistors are side by side on the substrate in the second direction.

4. The high-frequency amplifier circuit according to claim 1, further comprising:
a signal input terminal to which a signal is input to the drive stage amplifier circuit;
a drive stage bias circuit configured to supply a bias to the plurality of drive stage transistors;
a power stage bias circuit configured to supply a bias to the plurality of power stage transistors; and
a bias power supply terminal configured to supply power to the drive stage bias circuit and to the power stage bias circuit,
wherein when viewed from the balun, the signal input terminal is farther than the drive stage amplifier circuit in the first direction, and
wherein the bias power supply terminal is outside of the minimally-sized with respect to the second direction, and between the short sides of the minimally-sized rectangle with respect to the first direction.

5. The high-frequency amplifier circuit according to claim 2, further comprising:
a signal input terminal to which a signal is input to the drive stage amplifier circuit;
a drive stage bias circuit configured to supply a bias to the plurality of drive stage transistors;
a power stage bias circuit configured to supply a bias to the plurality of power stage transistors; and
a bias power supply terminal configured to supply power to the drive stage bias circuit and to the power stage bias circuit,
wherein when viewed from the balun, the signal input terminal is farther than the drive stage amplifier circuit in the first direction, and
wherein the bias power supply terminal is outside of the minimally-sized with respect to the second direction, and between the short sides of the minimally-sized rectangle with respect to the first direction.
